(19) United States
(12) Patent Application Publication
(10) Pub. No.: US 2014/0168905 A1
(43) Pub. Date: Jun. 19, 2014

(54) ELECTRIC BOX WITH WIRE PROTECTION MECHANISM

(71) Applicant: ENERGY PRO TECHNOLOGY CO., LTD., Yilan County (TW)

(72) Inventor: Po-Nien KO, Taichung City (TW)

(73) Assignee: ENERGY PRO TECHNOLOGY CO., LTD., Yilan County (TW)

(21) Appl. No.: 13/716,152

(22) Filed: Dec. 16, 2012

(51) Int. Cl. H05K 5/00

(52) U.S. Cl. CPC H05K 5/0026; H05K 5/0004
USPC 361/728; 361/679.01; 361/748

(57) ABSTRACT

The electric box includes a box body, a control assembly and a protection structure. The box body has a chamber. The control assembly is received in the chamber. The protection structure includes a protector and at least one passing hole located on a side of the box body and communicating with the chamber. The protector is received in the chamber and located on a side of the control assembly. The protector is provided with at least one through hole corresponding to the at least one passing hole. The passing hole and through hole are used for being passed by a wire.

### BACKGROUND OF THE INVENTION

1. Technical Field

The invention relates to electric boxes, particularly to an electric box with a wire protection mechanism for a lamp.

2. Related Art

Nowadays, in the field of LED lighting, the LED light source requires a starter for providing an instantaneous pulse to drive it.

A conventional electric box includes a box body, a circuit board and connecting terminals. The circuit board is received in the box body. A portion of the connecting terminals is received in the box body to electrically connect with the circuit board and the other portion thereof protrudes from the box body. Wires are connected to the circuit board through the connecting terminals.

Such an electric box has drawbacks as follows:

1. The exposed connecting terminals cannot be insulated by tape, so a user is easy to get an electric shock due to touching the connecting terminals.

2. The exposed connecting terminals tend to rust out because of moisture.

### SUMMARY OF THE INVENTION

An object of the invention is to provide an electric box with a wire protection mechanism, which connects the wires with the circuit board by using a protector to prevent the wires from being directly exposed to moisture in the air and being undesiredly touched by a user.

To achieve the above object, the electric box of the invention includes a box body, a control assembly and a protection structure. The box body has a chamber. The control assembly is received in the chamber. The protection structure includes a protector and at least one passing hole located on a side of the box body and communicating with the chamber. The protector is received in the chamber and located on a side of the control assembly. The protector is provided with at least one through hole corresponding to the at least one passing hole. The passing hole and through hole are used for being passed by a wire.

Besides, a copper cord of the wire can be protected by the protector to prevent the copper cord from exposing in the air. This can avoid the wire to rust out. Additionally, when the protector is provided with two or more passing holes, two or more wires can separately pass through the passing holes to avoid a short and electric shock. When using the wire fastener to fix the wire, a tool such as a screw driver can be used to reach the first room through the operating hole. The plug covering the operating hole can resist water and dust. The electronic module is isolated in the second room to make a waterproof effect. This can enhance durability of the electronic module.

### BRIEF DESCRIPTION OF THE DRAWINGS

FIG. 1 is a perspective view of the invention;

FIG. 2 is an exploded view of the invention;

FIG. 3 is a schematic view showing the invention in use; and

FIG. 4 is a cross-sectional view of the invention in use.

### DETAILED DESCRIPTION OF THE INVENTION

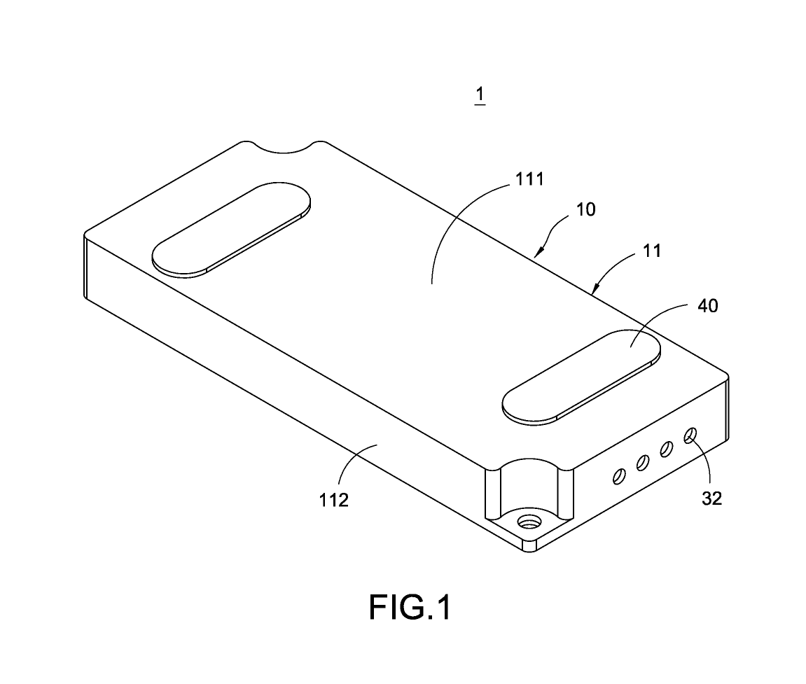

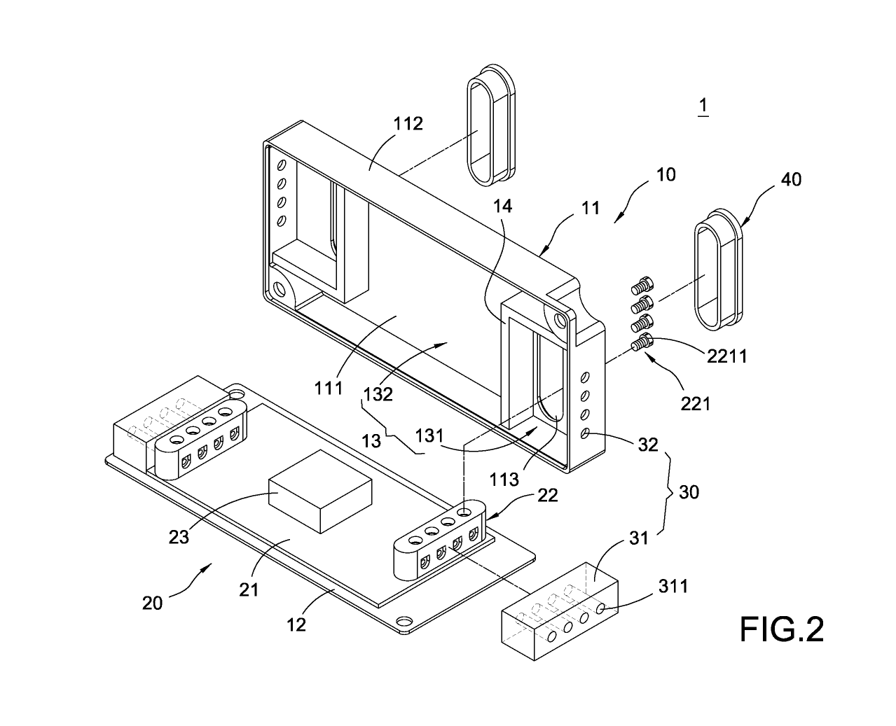

Please refer to FIGS. 1 and 2. The electric box 1 of the invention includes a box body 10, a control assembly 20 and a protection structure 30.

The box body 12 includes an upper cover 11 and a lower cover 12. The upper cover 11 is composed of a bottom 111 and a surrounding wall 112 extending from the bottom 111. The lower cover 12 is correspondingly fastened to the upper cover 11. A chamber 13 is formed by the upper and lower covers 11, 12. A partition wall 14 extends from the bottom 111 of the upper cover 11 to divide the chamber 13 into a first room 131 and a second room 132. The partition wall 14 is of an L-shape. Additionally, the bottom 111 is formed with an operating hole 113.

The control assembly 20 is received in the chamber 13 and includes a circuit board 21, a terminal block 22 and an electronic module 23. The electronic module 23 is located on a side of the circuit board 21 and in the second room 132. The electronic module 23 includes electronic components such as capacitors, resisters and ICs. The terminal block 23 is located on the circuit board 21 near a protector 31 and electrically connects to the circuit board 21. Also, the terminal block 22 is located in the first room 131. The electronic module 23 is located on the circuit board 21 and spaced with the terminal block 22. The terminal block 22 is provided with a wire fastener 221 corresponding to the operating hole 113. The wire fastener 221 can be screws 2211 or others.

The protection structure 31 includes a protector 31 and at least one passing hole 32. The protector 31 is located on the circuit board 21 and in the first room 32. The protector 31 is formed with at least one through hole 311 communicating with the first room 131. The passing hole 32 is located in the surrounding wall 112 near the protector 31, communicates with the first room 131 and corresponds to the through hole 311. The passing hole 32 and through hole 311 are used for being passed by a wire 9.

The electric box 1 further includes a plug 40 removably covering the operating hole 113.

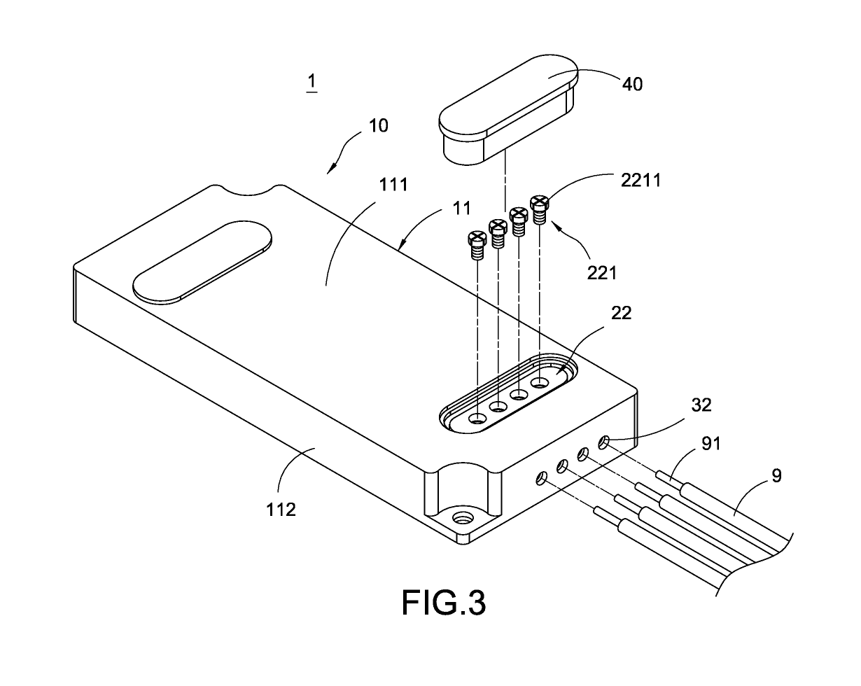

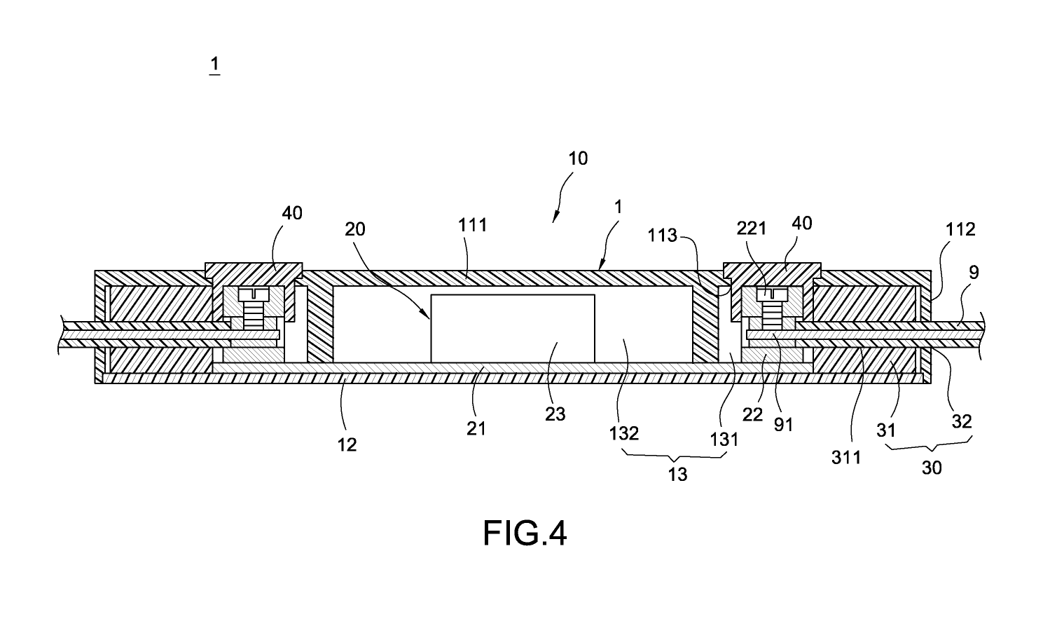

Please refer to FIGS. 3 and 4. When in use, the wire 9 penetrates passing hole 32 of the surrounding wall 112 and the through hole 311 of the protector 31 to electrically connect with the terminal block 22 and the circuit board 21. Finally, the wire 9 is fixed on the terminal block 22 by the wire fastener 221.

By the structure of the invention, copper cord 91 of the wire 9 can be protected by the protector 31 to prevent the copper cord 91 from exposing in the air. This can avoid the wire 9 to rust out. Additionally, when the protector 31 is provided with two or more passing holes 32, two or more wires 9 can separately pass through the passing holes 32 to avoid a short and electric shock.

Furthermore, when using the wire fastener 221 to fix the wire 9, a tool such as a screw driver can be used to reach the first room 111 through the operating hole 111. The plug 40 covering the operating hole 113 can resist water and dust.

The electronic module 23 is isolated in the second room 132 to make a waterproof effect. This can enhance durability of the electronic module 23.

It will be appreciated by persons skilled in the art that the above embodiment has been described by way of example only and not in any limitative sense, and that various alterations and modifications are possible without departure from the scope of the invention as defined by the appended claims.

What is claimed is:

1. An electric box comprising:
a box body having a chamber;
a control assembly, received in the chamber; and
a protection structure, comprising a protector and at least one passing hole located on a side of the box body and communicating with the chamber, wherein the protector is received in the chamber and located on a side of the control assembly, the protector is provided with at least one through hole corresponding to the at least one passing hole, and the at least one passing hole and the at least one through hole are used for being passed by a wire.

2. The electric box of claim 1, wherein the box body includes an upper cover and a lower cover, a chamber is formed by the upper and lower covers, and the at least one passing hole is in the upper cover.

3. The electric box of claim 2, wherein the control assembly includes a circuit board and a terminal block, the protector is located on the circuit board, the terminal block is located on and electrically connected to the circuit board and near the protector, and the wire is electrically connected to the circuit board through the terminal block.

4. The electric box of claim 3, wherein a partition wall extends from the bottom of the upper cover to divide the chamber into a first room and a second room, and the terminal block and the protector are received in the first room.

5. The electric box of claim 4, wherein the control assembly comprises an electronic module on the circuit board and in the second room.

6. The electric box of claim 4, wherein the partition wall is of an L-shape.

7. The electric box of claim 4, wherein the upper cover is composed of a bottom and a surrounding wall extending from the bottom, and the passing hole is in the surrounding wall.

8. The electric box of claim 7, wherein the terminal block is provided with a wire fastener for fixing the wire on the terminal block.

9. The electric box of claim 8, wherein the bottom is formed with an operating hole in the first room, and the operating hole is removably covered by a plug.
